(19) United States
(12) Patent Application Publication
(10) Pub. No.: US 2019/0372210 A1
(43) Pub. Date: Dec. 5, 2019

(54) WIRELESS MODULE AND ELECTRONIC DEVICE

(71) Applicant: TAIYO YUDEN CO., LTD., Tokyo (JP)

(72) Inventor: Jin MIKATA, Takasaki-shi (JP)

(21) Appl. No.: 16/418,789

(22) Filed: May 21, 2019

(30) Foreign Application Priority Data
May 31, 2018 (JP) 2018-105114

(51) Int. Cl. H01Q 1/40; H01L 23/31; H01L 23/66; H01L 23/552; H01L 21/56; H01Q 1/38

(52) U.S. Cl. CPC H01Q 1/40; H01L 23/3121; H01L 23/66; H01Q 1/526; H01L 21/565; H01Q 1/38; H01L 2223/6677; H01L 23/552

(57) ABSTRACT

A wireless module includes: a substrate having a first surface and a second surface, the second surface being an opposite surface of the substrate from the first surface; an antenna located on the first surface; an electronic circuit that is located on the first surface and/or the second surface, and outputs a high-frequency signal to the antenna and/or receives a high-frequency signal from the antenna; and a foamed resin located on the first surface so as to seal the antenna.

### CROSS-REFERENCE TO RELATED APPLICATION

This application is based upon and claims the benefit of priority of the prior Japanese Patent Application No. 2018-105114, filed on May 31, 2018, the entire contents of which are incorporated herein by reference.

### FIELD

A certain aspect of the present disclosure relates to a wireless module, a method of manufacturing the same, and an electronic device.

### BACKGROUND

There has been known a wireless module that has an antenna on the surface of a substrate and includes electronic circuits for transmission and reception mounted on the substrate. It has been known that the antenna and the electronic circuits are sealed with use of a resin as disclosed in, for example, Japanese Patent Application Publication No. 2014-179821 (hereinafter, referred to as Patent Document 1).

### SUMMARY OF THE INVENTION

According to a first aspect of the present invention, there is provided a wireless module including: a substrate having a first surface and a second surface, the second surface being an opposite surface of the substrate from the first surface; an antenna located on the first surface; an electronic circuit that is located on the first surface and/or the second surface, and outputs a high-frequency signal to the antenna and/or receives a high-frequency signal from the antenna; and a foamed resin located on the first surface so as to seal the antenna.

According to a second aspect of the present invention, there is provided an electronic device including: a mounting board having an upper surface on which an electronic component is mounted; a wireless module that is mounted on the upper surface of the mounting board, and includes a substrate, an antenna located on an upper surface of the substrate, an electronic circuit that is located on the upper surface of the substrate and outputs a high-frequency signal to the antenna and/or receives a high-frequency signal from the antenna, and a foamed resin that seals the antenna and does not cover the electronic circuit; and a sealing resin integrally sealing the electronic component and the electronic circuit.

According to a third aspect of the present invention, there is provided a wireless module including: a substrate of which a planar shape is a rectangle, the substrate having a first portion and a second portion; an antenna having a conductive pattern located in the first portion, the first portion being located closer to a first side of the rectangle of the substrate than the second portion; an electronic circuit located in the second portion, the second portion being located closer to a second side facing the first side of the substrate than the first portion; a foamed resin sealing the antenna; a sealing resin that seals at least a part of the electronic circuit; and a shield that is electrically connected to a ground wiring line or a ground electrode in a location located away from a region where the foamed resin is located, and seals the sealing resin.

### BRIEF DESCRIPTION OF THE DRAWINGS

FIG. 1A is a plan view of a wireless module in accordance with a first embodiment, and FIG. 1B is a cross-sectional view taken along line A-A in FIG. 1A;

FIG. 2A through FIG. 2C are cross-sectional views of wireless modules in accordance with first through third variations of the first embodiment, respectively;

FIG. 3A through FIG. 3D are cross-sectional views of wireless modules in accordance with fourth through seventh variations of the first embodiment, respectively;

FIG. 4A is a plan view illustrating a method of manufacturing an electronic device in accordance with a second embodiment, and FIG. 4B is a cross-sectional view taken along line A-A in FIG. 4A;

FIG. 5A is a plan view of the electronic device in accordance with the second embodiment, and FIG. 5B is a cross-sectional view taken along line A-A in FIG. 5A;

FIG. 6A is a plan view of an electronic device in accordance with a first variation of the second embodiment, and FIG. 6B is a cross-sectional view taken along line A-A in FIG. 6A;

FIG. 7A is a plan view illustrating a method of manufacturing a wireless module in accordance with a third embodiment, and FIG. 7B is a cross-sectional view taken along line A-A in FIG. 7A;

FIG. 8A is a plan view illustrating the method of manufacturing the wireless module in accordance with the third embodiment, and FIG. 8B is a cross-sectional view taken along line A-A in FIG. 8A;

FIG. 9A is a plan view illustrating the method of manufacturing the wireless module in accordance with the third embodiment, and FIG. 9B is a cross-sectional view taken along line A-A in FIG. 9A;

FIG. 10A is a plan view illustrating the method of manufacturing the wireless module in accordance with the third embodiment, and FIG. 10B is a cross-sectional view taken along line A-A in FIG. 10A;

FIG. 11A is a plan view illustrating the method of manufacturing the wireless module in accordance with the third embodiment, and FIG. 11B is a cross-sectional view taken along line A-A in FIG. 11A;

FIG. 12A is a plan view illustrating the method of manufacturing the wireless module in accordance with the third embodiment, and FIG. 12B is a cross-sectional view taken along line A-A in FIG. 12A;

FIG. 13A is a plan view illustrating the method of manufacturing the wireless module in accordance with the third embodiment, and FIG. 13B is a cross-sectional view taken along line A-A in FIG. 13A;

FIG. 14A is a plan view illustrating a method of manufacturing a wireless module in accordance with a fourth embodiment, and FIG. 14B is a cross-sectional view taken along line A-A in FIG. 14A;

FIG. 15A is a plan view illustrating the method of manufacturing the wireless module in accordance with the fourth embodiment, and FIG. 15B is a cross-sectional view taken along line A-A in FIG. 15A;

FIG. 16A is a plan view illustrating the method of manufacturing the wireless module in accordance with the fourth embodiment, and FIG. 16B is a cross-sectional view taken along line A-A in FIG. 16A;

FIG. 17A is a plan view illustrating the method of manufacturing the wireless module in accordance with the fourth embodiment, and FIG. 17B is a cross-sectional view taken along line A-A in FIG. 17A;

FIG. 18A is a plan view illustrating the method of manufacturing the wireless module in accordance with the fourth embodiment, and FIG. 18B is a cross-sectional view taken along line A-A in FIG. 18A;

FIG. 19 is a cross-sectional view illustrating the method of manufacturing the wireless module in accordance with the fourth embodiment; and

FIG. 20A and FIG. 20B are cross-sectional views of wireless modules in accordance with a fifth embodiment and a first variation of the fifth embodiment.

### DETAILED DESCRIPTION

As described above, it has been known that an antenna and electronic circuits of a wireless module are sealed with use of a resin. However, when a resin is provided so as to cover the antenna, the impedance of the antenna changes, and the characteristics of the antenna change. It may be also considered not to provide the resin covering the antenna. However, when the resin is not provided, the antenna is not protected.

Hereinafter, with reference to the accompanying drawings, embodiments of the present disclosure will be described.

### First Embodiment

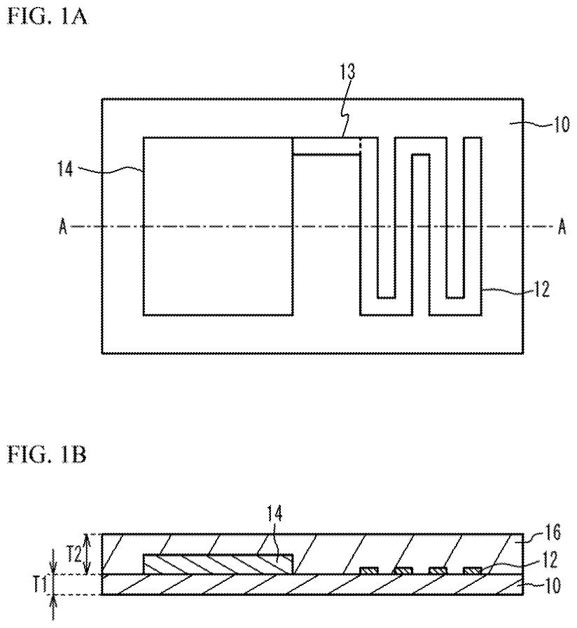

FIG. 1A is a plan view of a wireless module in accordance with a first embodiment, and FIG. 1B is a cross-sectional view taken along line A-A in FIG. 1A. Illustration of a foamed resin is omitted in FIG. 1A. As illustrated in FIG. 1A and FIG. 1B, an antenna 12 is formed on the upper surface of a substrate 10. An electronic circuit 14 is mounted on the upper surface of the substrate 10. A foamed resin 16 is located on the upper surface of the substrate 10 so as to cover the antenna 12 and the electronic circuit 14.

The substrate 10 is, for example, a multilayer board in which insulating layers are stacked. The insulating layer is, for example, a resin layer such as, but not limited to, an epoxy resin layer or a polyimide resin layer, or a ceramic layer such as a sintered ceramic layer. The resin layer may contain fibers or fillers for reinforcement. The thickness T1 of the substrate 10 is, for example, 0.1 mm to 1 mm. The antenna 12 is an antenna pattern formed of a conductive layer made of, for example, copper, gold, silver, or aluminum. The planar shape of the antenna 12 is a meander shape. The antenna 12 may be, for example, a patch antenna. A wiring line 13 is formed of the same conductive film as the antenna 12, and electrically connects the main part of the antenna 12 and the electronic circuit 14.

The electronic circuit 14 is, for example, an electronic component such as, but not limited to, an integrated circuit in which an electronic circuit is formed on a semiconductor substrate and is resin-sealed. The electronic circuit 14 includes, for example, a transmit circuit, a receive circuit, a power source circuit, and an interface circuit. The transmit circuit outputs, to the antenna 12, a high-frequency signal to be output from the antenna 12. The receive circuit receives, from the antenna 12, a high-frequency signal input to the antenna 12. The power source circuit supplies a source voltage to the transmit circuit, the receive circuit, and the interface circuit. The interface circuit is a circuit that receives, from an external device, a signal to be output from the receive circuit and outputs, to the external device, a signal input to the transmit circuit. The frequency of radio waves received/transmitted by the antenna 12 is, for example, 0.8 GHz to 5 GHz. For example, the wireless module is a Bluetooth (registered trademark) module of which the frequency is 2.4 GHz.

The electronic circuit 14 covered with the foamed resin 16 may have components constituting the electronic circuit 14 mounted on the substrate 10 and a metal shield case located so as to cover the components. The electronic circuit 14 may be a module having components constituting the electronic circuit 14 and a resin sealing the components. Furthermore, the electronic circuit 14 may be sealed, by resin, as a package such as, but not limited to, a multi chips package (MCP). A metallic film may be formed on the surface of the sealing resin by sputtering or plating. Since the foamed resin 16 has foamed void spaces, the foamed resin 16 has an environmental resistance inferior to those of a transfer molding package and a vacuum printing package. Thus, the environmental resistance of the electronic circuit 14 is improved by covering the electronic circuit 14 by a metal case or a metallic film, and then covering the metal case or the metallic film with a foamed resin.

The foamed resin 16 is a resin in which gas is dispersed in a synthetic resin. The ratio of the volume of the gas to the volume of the whole foamed resin is, for example, 90% or greater. Examples of the synthetic resin include, but are not limited to, polyurethane, polystyrene, and polyolefin. The thickness T2 of the foamed resin 16 is, for example, 0.1 mm to 1 mm. The thickness T2 is greater than, for example, the thickness T1 of the substrate 10. The structure of the foamed resin is classified into two structures: an open-cell structure and a closed-cell structure according to the structure of the foam. The foamed resin 16 may have any one of the structures, but the closed-cell structure is preferable from the view point of the environmental resistance. When the open-cell structure and the closed-cell structure coexist, closed-cells are preferably present more than open-cells. The same applies to the embodiments hereinafter.

### First Variation of the First Embodiment

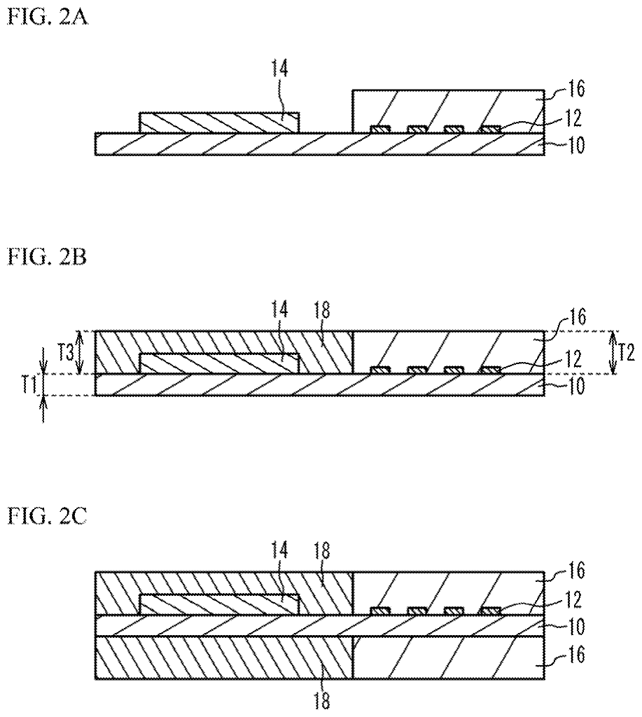

FIG. 2A through FIG. 2C are cross-sectional views of wireless modules in accordance with first through third variations of the first embodiment, respectively. As illustrated in FIG. 2A, in the wireless module of the first variation of the first embodiment, the foamed resin 16 is located on the antenna 12, but is not located on the electronic circuit 14. As seen above, the foamed resin 16 may not necessarily cover the electronic circuit 14. Other structures are the same as those of the first embodiment, and the description thereof is thus omitted.

As in the first embodiment, the foamed resin 16 may seal the antenna 12 and the electronic circuit 14. Alternatively, as in the first variation of the first embodiment, the foamed resin 16 may seal the antenna 12, and may not necessarily seal the electronic circuit 14.

### Second Variation of the First Embodiment

As illustrated in FIG. 2B, in the wireless module of the second variation of the first embodiment, the electronic circuit 14 is located on the upper surface of the substrate 10, and a sealing resin 18, which seals the electronic circuit 14, is located on the upper surface of the substrate 10. The sealing resin 18 is not a foamed resin, and is, a thermosetting resin such as, but not limited to, an epoxy resin or a thermoplastic resin. The density of the sealing resin 18 is greater than that of the foamed resin 16. The thickness T3 of the sealing resin 18 is approximately equal to, for example, the thickness T2 of the foamed resin 16. Other structures are the same as those of the first variation of the first embodiment, and the description thereof is thus omitted.

### Third Variation of the First Embodiment

As illustrated in FIG. 2C, in the wireless module of the third variation of the first embodiment, the foamed resin 16 is located on the lower surface of the substrate 10 so as to overlap with the antenna 12 in the thickness direction of the substrate 10. The sealing resin 18 is located on the lower surface of the substrate 10 so as to overlap with the electronic circuit 14 in the thickness direction of the substrate 10. Other structures are the same as those of the second variation of the first embodiment, and the description thereof is thus omitted. In FIG. 2A through FIG. 2C, the electronic circuit 14 may be hermetically sealed by a metal shield case. The electronic circuit 14 may have a structure in which the electronic circuit 14 is sealed by a resin package (for example, an MCP), and a metallic film is located on the resin surface. As seen above, the electronic circuit 14 may have a shield structure.

### Fourth Variation of the First Embodiment

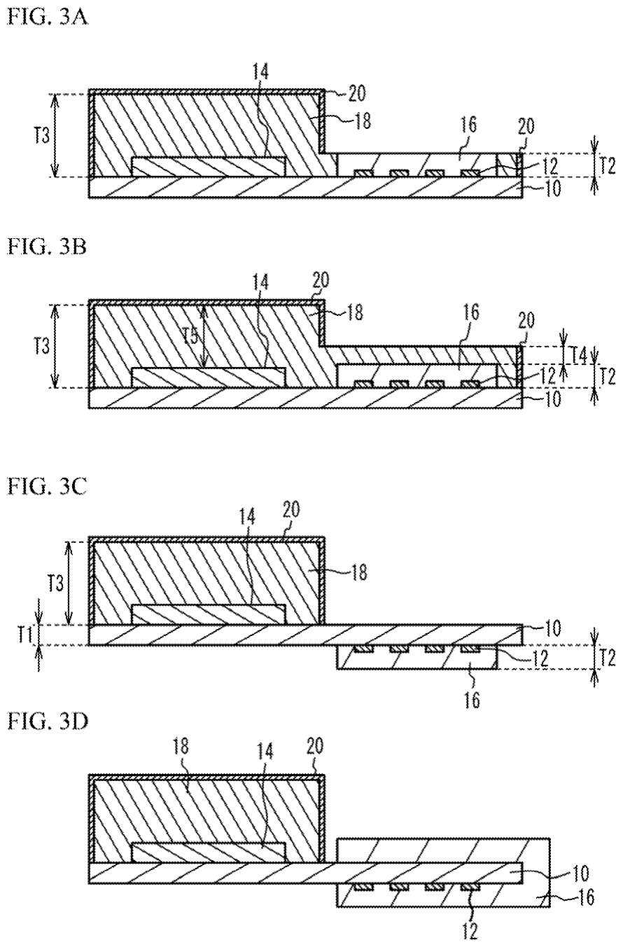

FIG. 3A through FIG. 3D are cross-sectional views of wireless modules in accordance with fourth through seventh variations of the first embodiment, respectively. As illustrated in FIG. 3A, in the wireless module of the fourth variation of the first embodiment, the antenna 12 and the electronic circuit 14 are located on the upper surface of the substrate 10. The foamed resin 16 is provided so as to seal the antenna 12, and the sealing resin 18 is provided so as to seal the electronic circuit 14. The thickness T2 of the foamed resin 16 is less than the thickness T3 of the sealing resin 18. A shield layer 20 is located on the surface of the sealing resin 18. The shield layer 20 is a conductive layer of which the main material is, for example, gold, silver, copper, aluminum, or nickel. Alternatively, the shield layer 20 may be formed of a multilayered film including films made of materials selected from these metals. Yet alternatively, the shield layer 20 may be a multilayered film of a Cu film and a stainless steel film. Other structures are the same as those of the first embodiment, and the description thereof is thus omitted.

As in the fourth variation of the first embodiment, the sealing resin 18 may seal the electronic circuit 14, and the sealing resin 18 may be covered with the shield layer 20. This structure reduces electromagnetic interference (EMI) generated from the electronic circuit 14. The foamed resin 16 is exposed from the sealing resin 18, and the shield layer 20 is not located on the foamed resin 16. This structure inhibits from radio waves transmitted/received by the antenna 12 from being attenuated by the sealing resin 18 and the shield layer 20. The thickness T2 of the foamed resin 16 around the antenna 12 is less than the thickness T3 of the sealing resin 18 around the electronic circuit 14.

### Fifth Variation of the First Embodiment

As illustrated in FIG. 3B, in the wireless module of the fifth variation of the first embodiment, the sealing resin 18 is located on the foamed resin 16 on the antenna 12. Other structures are the same as those of the fourth variation of the first embodiment, and the description thereof is thus omitted.

Since the sealing resin 18 is located on the foamed resin 16, the antenna 12 is protected from water and mechanical shock compared with that of the fourth variation of the first embodiment. The thickness T4 of the sealing resin 18 on the foamed resin 16 is less than the thickness T5 of the sealing resin 18 on the electronic circuit 14.

### Sixth Variation of the First Embodiment

As illustrated in FIG. 3C, in the wireless module of the sixth variation of the first embodiment, the antenna 12 is located on the lower surface of the substrate 10. The foamed resin 16 is located on the lower surface of the substrate 10 so as to seal the antenna 12. The electronic circuit 14 is located on the upper surface of the substrate 10. The sealing resin 18 is located on the upper surface of the substrate 10 so as to seal the electronic circuit 14. The sealing resin 18 is not provided so as to overlap with the antenna 12. The thickness T2 of the foamed resin 16 is less than the thickness T3 of the sealing resin 18. The shield layer 20 is located on the surface of the sealing resin 18. Other structures are the same as those of the second variation of the first embodiment, and the description thereof is thus omitted.

### Seventh Variation of the First Embodiment

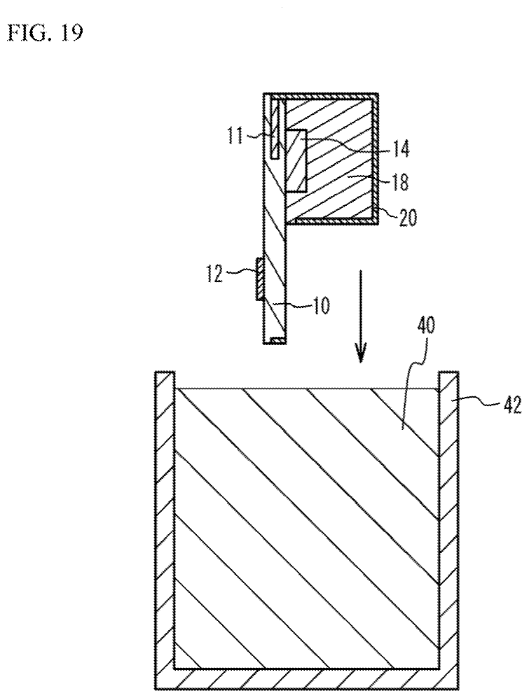

As illustrated in FIG. 3D, in the wireless module of the seventh variation of the first embodiment, the foamed resin 16 is located on the upper and lower surfaces of the substrate 10 so as to overlap with the antenna 12 in plan view. Other structures are the same as those of the sixth variation of the first embodiment, and the description thereof is thus omitted. In this case, as described later in FIG. 19, the foamed resin 16 is easily formed by immersing the substrate 10 having the antenna 12 formed thereon into melted foamed resin.

As in the sixth and seventh variations of the first embodiment, the antenna 12 may be located on the opposite surface from the surface on which the electronic circuit 14 is located. The sealing resin 18 preferably does not overlap with the antenna 12 in plan view.

In the first embodiment and the variations thereof, the antenna 12 is located on a first surface of the substrate 10. The first surface on which the antenna 12 is located is the upper surface of the substrate 10 in the first embodiment and the first through fifth variations thereof, while the first surface is the lower surface of the substrate 10 in the sixth and seventh variations of the first embodiment. The electronic circuit 14 is located on the first surface, on which the antenna 12 is located, of the substrate 10, or is located on a second surface that is an opposite surface of the substrate 10 from the first surface. The electronic circuit 14 is mounted on the first surface on which the antenna 12 is also located in the first embodiment and the first through fifth variations thereof, while the electronic circuit 14 is mounted on the second surface opposite from the first surface on which the antenna 12 is located in the sixth and seventh variations of the first embodiment. The electronic circuit 14 may be located on both the first surface and the second surface.

The electronic circuit 14 is disposed so as not to overlap with the antenna 12 in the thickness direction of the substrate 10, and outputs high-frequency signals to the antenna 12 and/or receives high-frequency signals from the antenna 12. The foamed resin 16 is located on at least the first surface of the substrate 10 so as to seal the antenna 12.

Since the foamed resin 16 is mostly formed of gas, the radio waves transmitted/received by the antenna 12 do not attenuate. The relative permittivity of the foamed resin 16 is closer to the relative permittivity of air than the relative permittivity of the sealing resin 18. Thus, the characteristics, including impedance, of the antenna 12 hardly change between before and after formation of the foamed resin 16. Therefore, the change in the antenna characteristic due to the sealing resin 18 is reduced.

As in the first through seventh variations of the first embodiment, the foamed resin 16 may not necessarily cover the electronic circuit 14. This structure allows the sealing resin 18 to be provided on the upper surface of the substrate 10 (the surface on which the electronic circuit 14 is located of the first surface and the second surface) so as to cover the electronic circuit 14 as in the second through seventh variations of the first embodiment. The sealing resin 18 is not a foamed resin, and has a greater density than the foamed resin 16. Thus, the sealing resin 18 is able to further protect the electronic circuit 14. The density of the sealing resin 18 is equal to or greater than, for example, five times the density of the foamed resin 16, preferably equal to or greater than ten times the density of the foamed resin 16.

As in the second through fourth, sixth, and seventh variations of the first embodiment, the sealing resin 18 does not overlap with the antenna 12 in the thickness direction of the substrate 10. This structure inhibits radio waves transmitted from/received by the antenna 12 from attenuating. In addition, the change in antenna characteristics is further reduced.

As in the fifth variation of the first embodiment, the sealing resin 18 may be provided so as to cover the foamed resin 16. Since the antenna 12 is covered with the foamed resin 16, even when the sealing resin 18 is located on the foamed resin 16, the change in antenna characteristic is small. Since the sealing resin 18 seals the foamed resin 16, the foamed resin 16 is mechanically protected. In addition, the antenna 12 is protected from water or the like.

The thickness T4 of the sealing resin 18 on the foamed resin 16 is configured to be less than the thickness T5 of the sealing resin 18 on the electronic circuit 14. This structure further reduces the change in antenna characteristics due to the sealing resin 18.

As in the fourth through seventh variations of the first embodiment, the shield layer 20 is provided so as to cover the sealing resin 18, and does not overlap with the antenna 12 in the thickness direction of the substrate 10. This structure reduces EMI from the electronic circuit 14.

As in the first embodiment, the foamed resin 16 seals the electronic circuit 14. This structure protects the electronic circuit 14.

As in the third and seventh variations of the first embodiment, the foamed resin 16 is located on the opposite surface (the second surface) of the substrate 10 from the surface on which the antenna 12 is located so that the foamed resin 16 overlaps with the antenna 12 in the thickness direction of the substrate 10.

When the sealing resin is located on the opposite surface from the surface on which the antenna 12 is located so that the sealing resin overlaps with the antenna 12, the impedance or the like of the antenna 12 changes. In the third and seventh variations of the first embodiment, the foamed resin 16 is located on the upper and lower surfaces (the first surface and the second surface) of the substrate 10 so that the foamed resin 16 overlaps with the antenna 12 in the thickness direction of the substrate 10. This structure inhibits the antenna characteristics from changing. In the fourth through seventh variations of the first embodiment, the electronic circuit 14 may be covered with the foamed resin 16, and the sealing resin 18 may cover the foamed resin 16.

### Second Embodiment

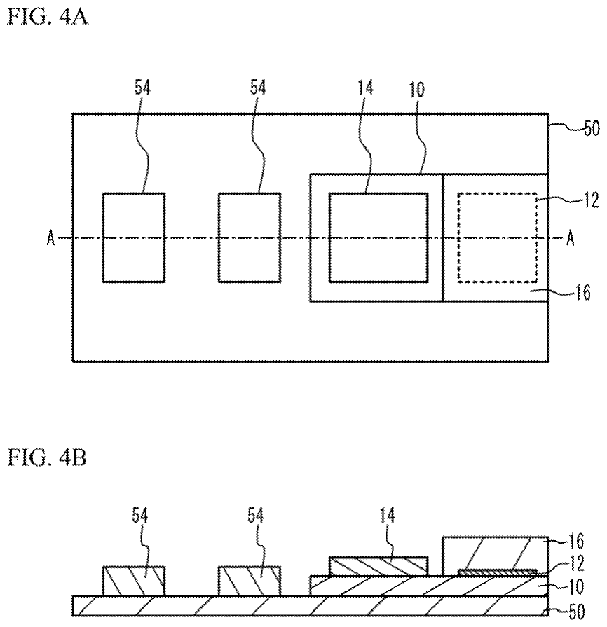

A second embodiment is an exemplary electronic device in which a wireless module is mounted. FIG. 4A is a plan view illustrating a method of manufacturing the electronic device in accordance with the second embodiment, and FIG. 4B is a cross-sectional view taken along line A-A in FIG. 4A. In the drawings hereinafter, the planar shape of the antenna 12 is illustrated as a rectangle for simplification. As illustrated in FIG. 4A and FIG. 4B, in the electronic device of the second embodiment, the wireless module of the first variation of the first embodiment is mounted on the upper surface of a mounting board 50 such as a motherboard. The mounting board 50 is a multilayer board in which insulating layers such as, but not limited to, resin layers or ceramic layers are stacked. Electronic components 54 are mounted on the upper surface of the mounting board 50. The electronic component 54 and the electronic circuit 14 other than the antenna 12 are not sealed by the sealing resin 18. The electronic component 54 and the electronic circuit 14 may be typical package products sealed by transfer molding. The electronic component 54 is a bare chip and/or a chip size package (CSP) mounted on the mounting board 50 and/or the substrate 10, and may be resin-sealed on the mounting board 50 and/or the substrate 10 by potting so that the bare chip and/or the CSP is sealed. The electronic circuit 14 is a bare chip and/or a chip size package (CSP) mounted on the mounting board 50 and/or the substrate 10, and may be resin-sealed on the mounting board 50 and/or the substrate 10 by potting so that the bare chip and/or the CSP is sealed.

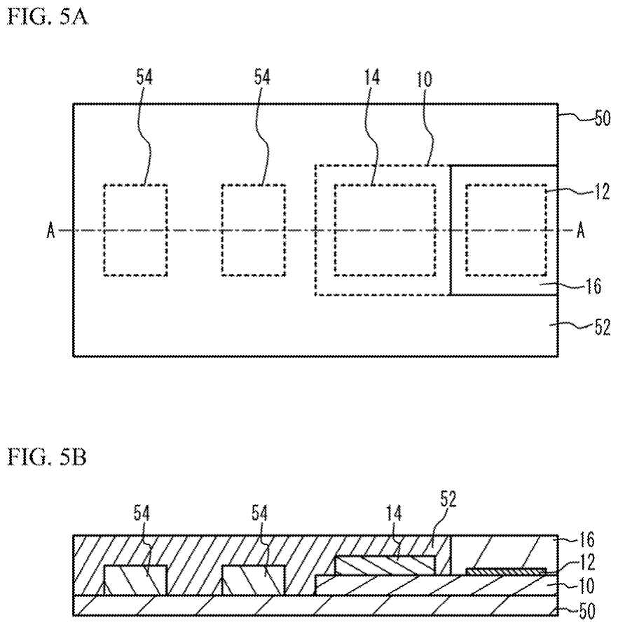

FIG. 5A is a plan view of the electronic device in accordance with the second embodiment, and FIG. 5B is a cross-sectional view taken along line A-A in FIG. 5A. A sealing resin 52 is formed on the upper surface of the mounting board 50 by potting or transfer molding. This process seals the electronic components 54 and the electronic circuit 14 by the sealing resin 52. The sealing resin 52 is not a foamed resin but a thermosetting resin such as an epoxy resin or a thermoplastic resin. The density of the sealing resin 52 is greater than the density of the foamed resin 16.

Since the antenna 12 is covered with the foamed resin 16 when the sealing resin 52 is formed, the antenna 12 is never directly covered with the sealing resin 52. Thus, the antenna characteristics of the antenna 12 are inhibited from changing after the wireless module is mounted. When the electronic circuit 14 is sealed by the foamed resin 16 as in the first embodiment, the protection of the electronic circuit 14 from mechanical shock and/or water is insufficient. In the second embodiment, the electronic components 54 and the electronic circuit 14 are sealed by the sealing resin 52. Thus, the electronic components 54 and the electronic circuit 14 can be protected from mechanical shock and/or water.

As in the first variation of the first embodiment, the foamed resin 16 does not cover the electronic circuit 14. This mold structure allows the electronic circuit 14 and/or the electronic component 54 to be sealed by the sealing resin 52 when the wireless module is mounted in the electronic device as in the second embodiment.

In addition, in the electronic component of the second embodiment, the wireless module is mounted on the upper surface of the mounting board 50 so that the lower surface of the substrate 10 of the wireless module of the first variation of the first embodiment faces the upper surface of the mounting board 50. The sealing resin 52 integrally seals the electronic components 54 and the electronic circuit 14 mounted on the upper surface of the mounting board 50. That is, the electronic components 54 and the electronic circuit 14 are sealed by the single sealing resin 52. This structure inhibits the antenna characteristics of the antenna 12 from changing, and protects the electronic components 54 and the electronic circuit 14.

### First Variation of the Second Embodiment

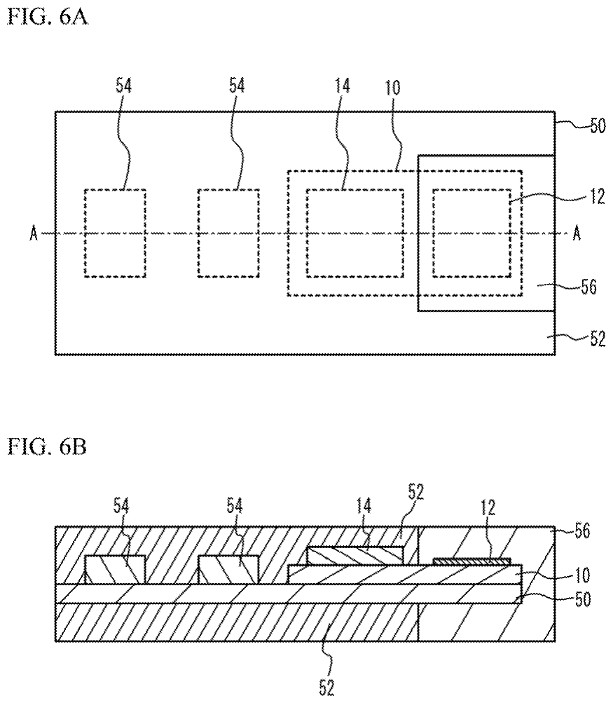

FIG. 6A is a plan view of an electronic device in accordance with a first variation of the second embodiment, and FIG. 6B is a cross-sectional view taken along line A-A in FIG. 6A. As illustrated in FIG. 6A and FIG. 6B, in the electronic device of the first variation of the second embodiment, a foamed resin 56 is located in the regions, overlapping with the antenna 12, on the upper and lower surfaces of the mounting board 50. The sealing resin 52 is located in the region other than the region where the foamed resin 56 is located on the upper surface and the lower surface of the mounting board 50. The material and configurations of the foamed resin 56 are the same as those of the foamed resin 16. Other structures are the same as those of the second embodiment, and the description thereof is thus omitted.

When the sealing resin 52 is formed in the regions overlapping with the antenna 12 on the upper and lower surfaces of the mounting board 50, the antenna characteristics of the antenna 12 change. Thus, as in the first variation of the second embodiment, the foamed resin 56 is provided in the regions overlapping with the antenna 12 on the upper and lower surfaces of the mounting board 50. This structure inhibits the antenna characteristics of the antenna 12 from changing.

### Third Embodiment

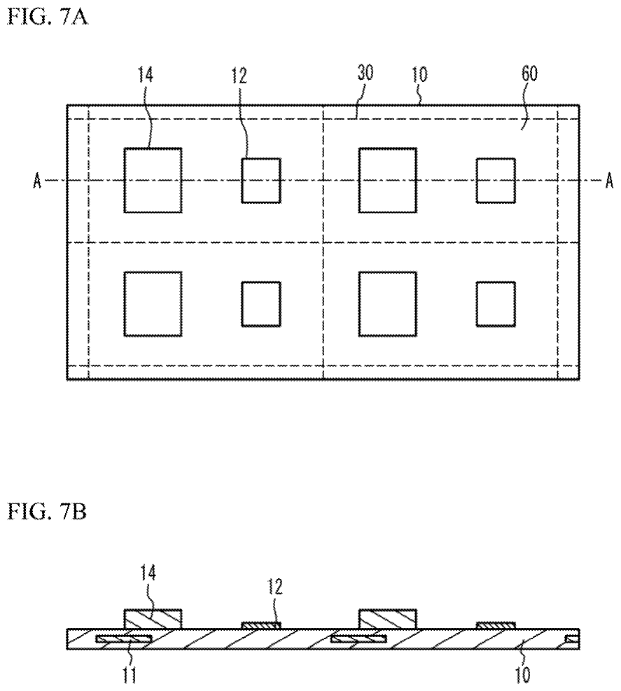

A third embodiment is an exemplary method of manufacturing the wireless module of the fourth variation of the first embodiment. FIG. 7A through FIG. 13B illustrate a method of manufacturing a wireless module in accordance with the third embodiment. FIG. 7A through FIG. 13A are plan views, and FIG. 7B through FIG. 13B are cross-sectional views taken along line A-A in FIG. 7A through FIG. 13A, respectively.

As illustrated in FIG. 7A and FIG. 7B, one unit 60 to be one product is indicated by a rectangle defined by section lines 30. An aggregate substrate in which the units 60 are arranged in a matrix form (in FIG. 7A, in a 2×2 matrix form) is prepared. The aggregate substrate corresponds to the substrate 10 in the drawings. In each unit 60, a conductive pattern formed of a metal film such as, but not limited to, a copper film is formed. The conductive pattern forms a wiring line, an electrode, and/or a land. Here, a description will be given by tentatively calling the conductive pattern a wiring line. A plurality of the antennas 12 are formed on the upper surface of the substrate 10. The antennas 12 are formed in the same step as the wiring lines formed on the substrate 10, and are formed of the same material as the wiring lines. The antennas 12 may be formed by screen printing or plating in a step separate from the step for forming the wiring line.

On the surface of the substrate 10 and inside the substrate 10, a wiring line or an electrode (not illustrated) for the electronic circuit is located adjacent to the region in which the antenna 12 is disposed. A ground wiring line 11 among the wiring lines (or a ground electrode among the electrodes) is a wiring line (or an electrode) to which a ground potential is supplied. A plurality of the electronic circuits 14 are mounted on the upper surface of the substrate 10. The electronic circuit 14 is, for example, a packaged electronic component, is mounted on the upper surface of the substrate 10 with use of solder or the like, and is electrically connected to a wiring line or an electrode located on the surface of the substrate 10 or inside the substrate 10. The section line 30 is an imaginary line along which the substrate 10 is to be cut. In FIG. 7A and FIG. 7B, described is a case where four (2×2) wireless modules are formed on one substrate 10, but a desired number of wireless modules can be formed on one substrate 10.

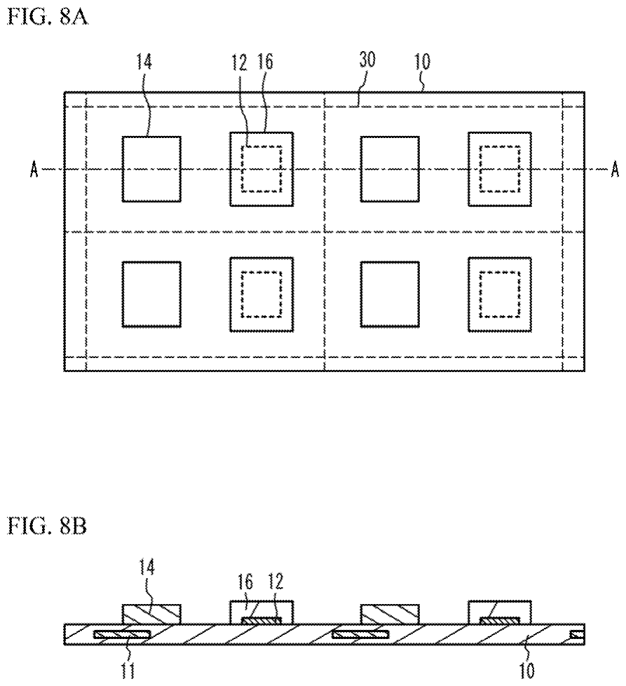

As illustrated in FIG. 8A and FIG. 8B, the foamed resin 16 is formed on the upper surface of the substrate 10 so as to cover the antennas 12. The foamed resin 16 is formed by, for example, potting or screen printing. The foamed resin 16 preferably covers the antenna 12 as completely as possible. As illustrated in FIG. 1A, in the boundary region from the region where the antenna 12 is disposed to the region where the electronic circuit 14 is disposed, the wiring line 13 integrally formed with the antenna 12 extends to the electronic circuit 14. The wiring line 13 is also a part of the antenna 12. The wiring line 13 is connected to the electronic circuit 14. Accordingly, at least a part near the connection point with the electronic circuit 14 of the wiring line 13 is not covered with the foamed resin 16. Thus, there may be a case where the foamed resin 16 cannot cover the pattern functioning as the antenna 12 entirely.

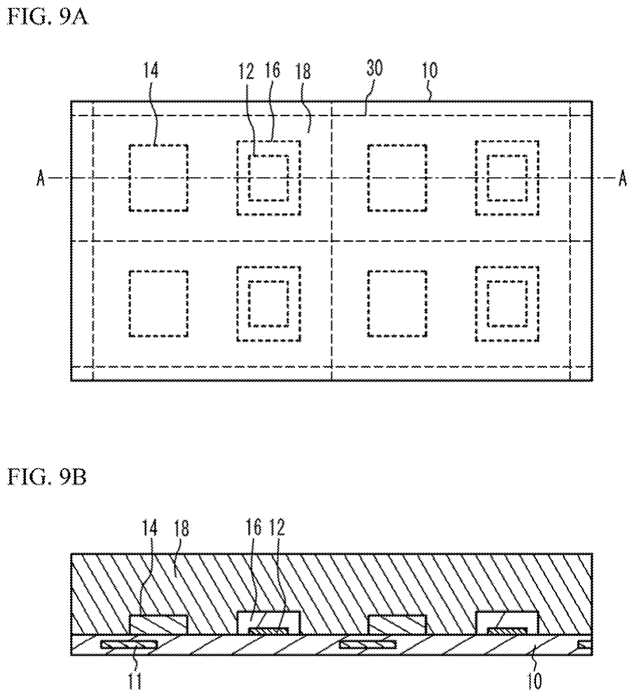

As illustrated in FIG. 9A and FIG. 9B, the sealing resin 18 is formed on the upper surface of the substrate 10 so as to cover a plurality of the foamed resins 16 and a plurality of the electronic circuits 14. The sealing resin 18 is formed by, for example, transfer molding or vacuum printing. When the sealing resin 18 is formed by transfer molding, a pressure is set at a pressure that does not crush the sealing resin 18.

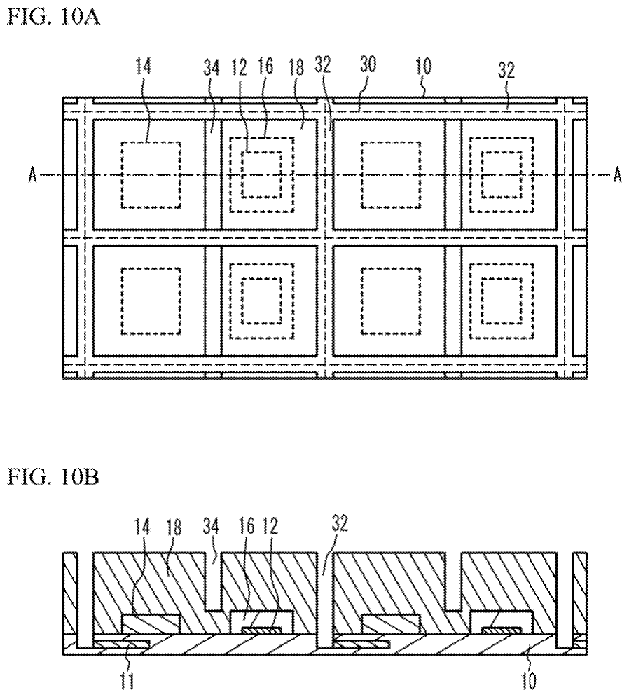

As illustrated in FIG. 10A and FIG. 10B, grooves 32 penetrating through the sealing resin 18 are formed along the section lines 30. When the ground wiring line 11 formed inside of the substrate is exposed from the substrate 10, the groove 32 is formed so as to reach the ground wiring line 11. Between the foamed resin 16 and the electronic circuit 14, a groove 34 is formed in at least the upper part of the sealing resin 18. The groove 34 is formed so as not to reach the substrate 10 so that the groove 34 does not cut the wiring lines on the surface of the substrate 10 and inside the substrate 10. The grooves 32 and 34 are formed by, for example, a dicing blade or a laser beam.

In FIG. 10B, the ground wiring line 11 (or a ground electrode) is located in the inner layer of the periphery of the substrate 10, but may be located on the upper surface of the periphery of the substrate 10. The groove 32 is formed so as to have a depth that allows the groove 32 to cut the ground wiring line 11 (a ground electrode). At least a part of the substrate 10 is left under the ground wiring line 11.

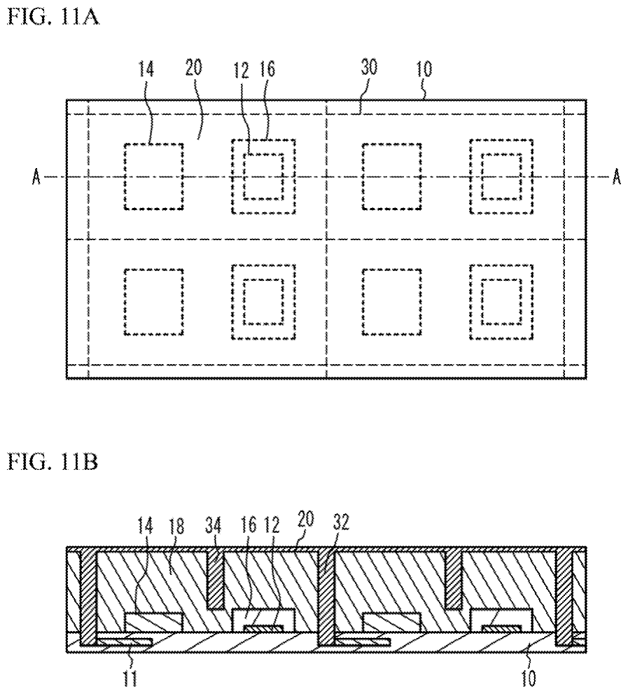

As illustrated in FIG. 11A and FIG. 11B, the shield layer 20 is formed on the surface of the sealing resin 18 so as to fill the grooves 32 and 34. The shield layer 20 is formed by, for example, vacuum printing, plating, or sputtering. When the shield layer 20 is formed by vacuum printing, a metal paste such as, but not limited to, a silver paste is printed. When the shield layer 20 is formed by plating or sputtering, the shield layer 20 of which the main material is a metal film such as, but not limited to, a gold film, a nickel film, or a copper film is formed. A seed layer may be formed, and then a plating film may be formed by plating. When the shield layer 20 is formed by sputtering, for example, a Cu film and a stainless steel film may be sequentially stacked as the shield layer 20.

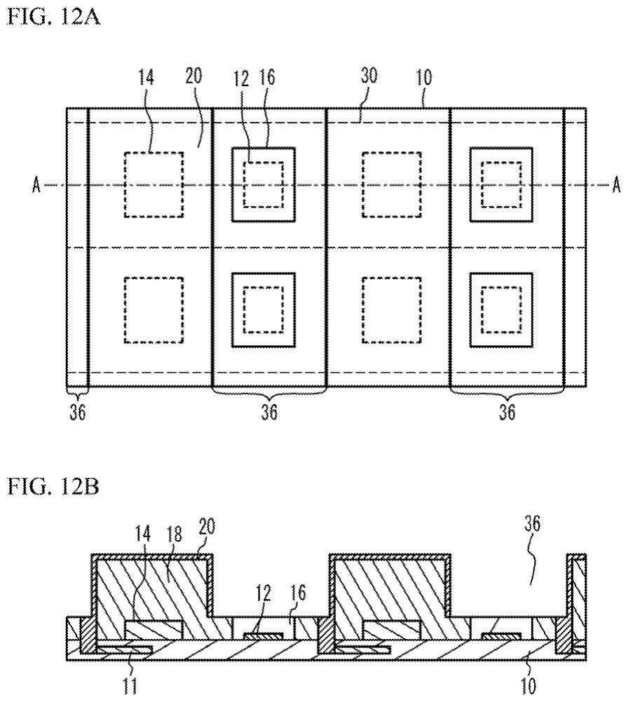

As illustrated in FIG. 12A and FIG. 12B, the shield layer 20 and the sealing resin 18 between the grooves 32 and 34 are removed. This process forms a recessed portion 36 between the grooves 32 and 34. The shield layer 20 and the sealing resin 18 are removed by cutting or irradiation of a laser beam. This process exposes the sealing resin 18. When the wireless module of the fifth variation of the first embodiment is manufactured, the upper part of the sealing resin 18 on the foamed resin 16 is removed to leave the lower part of the sealing resin 18.

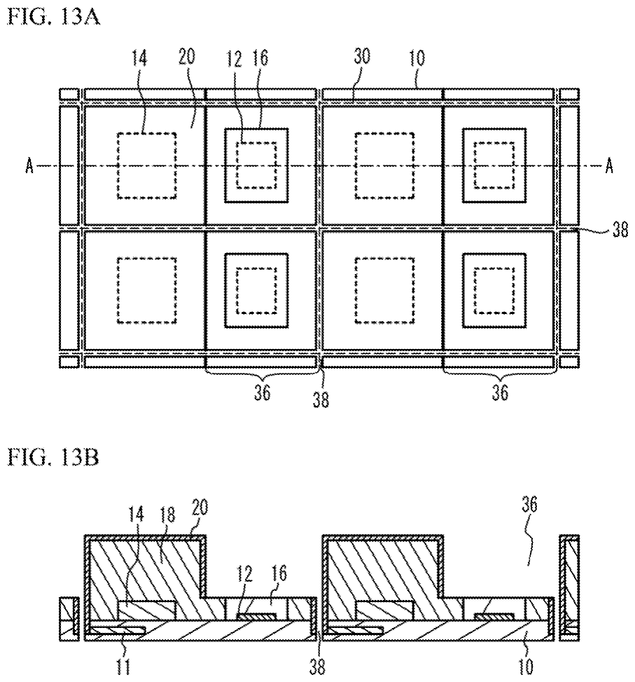

As illustrated in FIG. 13A and FIG. 13B, cutting grooves 38 are formed in the shield layer 20 and the substrate 10 in the section lines 30. This process cuts the shield layer 20 and the substrate 10. The shield layer 20 and the substrate 10 are cut by dicing using a dicing blade or laser dicing irradiating the shield layer 20 and the substrate 10 with a laser beam. This process separates the substrate 10 into individual modules, and the wireless modules of the fourth variation of the first embodiment are manufactured.

In the third embodiment, as illustrated in FIG. 8A and FIG. 8B, the foamed resin 16 that seals the antenna 12 and does not cover the electronic circuit 14 is formed on the upper surface of the substrate 10. As illustrated in FIG. 9A and FIG. 9B, the sealing resin 18 is formed on the upper surface of the substrate 10 so as to seal the foamed resin 16 and the electronic circuit 14. As illustrated in FIG. 12A and FIG. 12B, at least the upper part of the sealing resin 18 on the foamed resin 16 is removed without removing the sealing resin 18 on the electronic circuit 14.

Accordingly, a wireless module having a structure in which the foamed resin 16 seals the antenna 12, the sealing resin 18 seals the electronic circuit 14, and the sealing resin 18 on the foamed resin 16 is thin or is not provided is manufactured in a simple way.

As illustrated in FIG. 10A and FIG. 10B, the groove 32 (a first groove) reaching the upper surface of the substrate 10 is formed on the sealing resin 18 of the section line 30 (a region where the substrate 10 is to be cut), and the groove 34 (a second groove) not reaching the upper surface of the substrate 10 is formed in the sealing resin 18 between the foamed resin 16 and the electronic circuit 14. As illustrated in FIG. 11A and FIG. 11B, the shield layer 20 is formed on the inner surfaces of the grooves 32 and 34 and on the upper surface of the sealing resin 18. As illustrated in FIG. 12A and FIG. 12B, the shield layer 20 on the foamed resin 16 and at least the upper part of the sealing resin 18 between the groove 32 and the groove 34 are removed.

This process allows the shield layer 20 that covers the electronic circuit 14 and does not cover the antenna 12 to be formed in a simple way.

### Fourth Embodiment

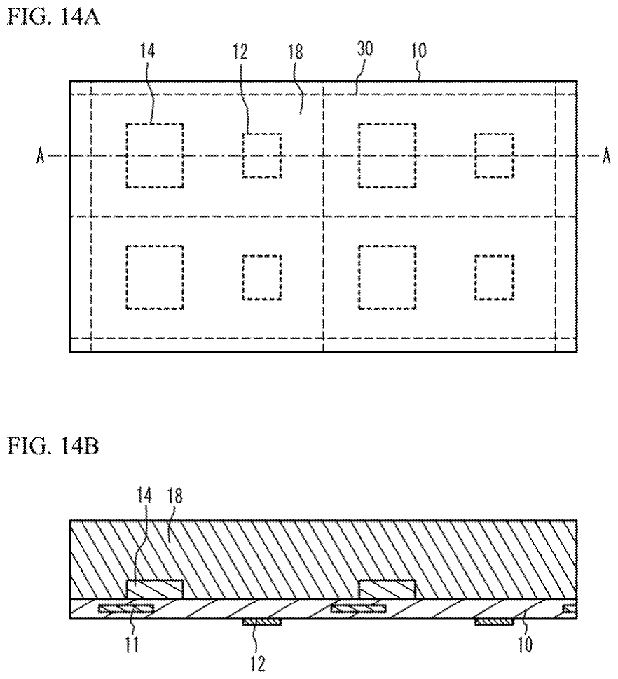

A fourth embodiment is an exemplary method of manufacturing the wireless module of the seventh variation of the first embodiment. FIG. 14A through FIG. 19 illustrate a method of manufacturing a wireless module of the fourth embodiment. FIG. 14A through FIG. 18A are plan views, and FIG. 14B through FIG. 18B are cross-sectional views taken along line A-A in FIG. 14A through FIG. 18A, respectively. FIG. 19 is a cross-sectional view.

As illustrated in FIG. 14A and FIG. 14B, with use of the same method as the method described in FIG. 7A and FIG. 7B of the third embodiment, a plurality of the antennas 12 are formed on the lower surface of the substrate 10. A plurality of the electronic circuits 14 are mounted on the upper surface of the substrate 10. With use of the same method as FIG. 9A and FIG. 9B, the sealing resin 18 is formed on the upper surface of the substrate 10 so as to cover the electronic circuits 14.

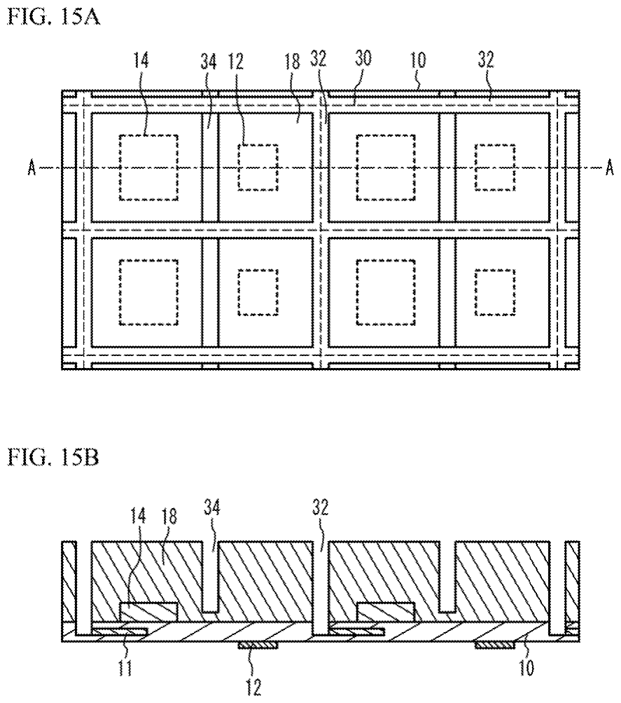

As illustrated in FIG. 15A and FIG. 15B, with use of the same method as FIG. 10A and FIG. 10B, the grooves 32 penetrating through the sealing resin 18 are formed along the section lines 30. The groove 34 is formed in at least the upper part of the sealing resin 18 between the antenna 12 and the electronic circuit 14. The depth of the groove 32 is adjusted depending on whether the ground wiring line 11 (or a ground electrode) is located on the surface or in the inner layer. When the substrate 10 is thin, the warpage of the substrate 10 due to the groove 32 becomes a problem. Thus, the ground wiring line 11 (or a ground electrode) may be formed on the upper surface of the substrate 10 or in the inner layer close to the upper surface, and the depth of the groove 32 may be configured to be small.

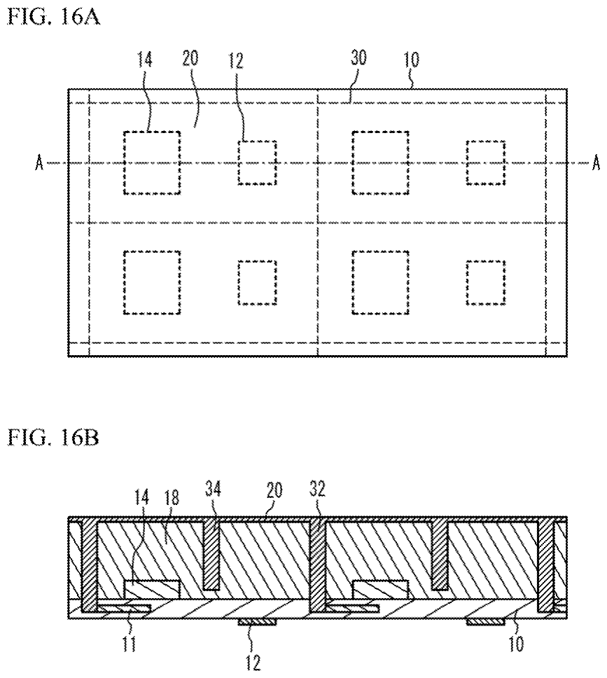

As illustrated in FIG. 16A and FIG. 16B, with use of the same method as the method described in FIG. 11A and FIG. 11B, the shield layer 20 is formed on the surface of the sealing resin 18 so as to fill the grooves 32 and 34.

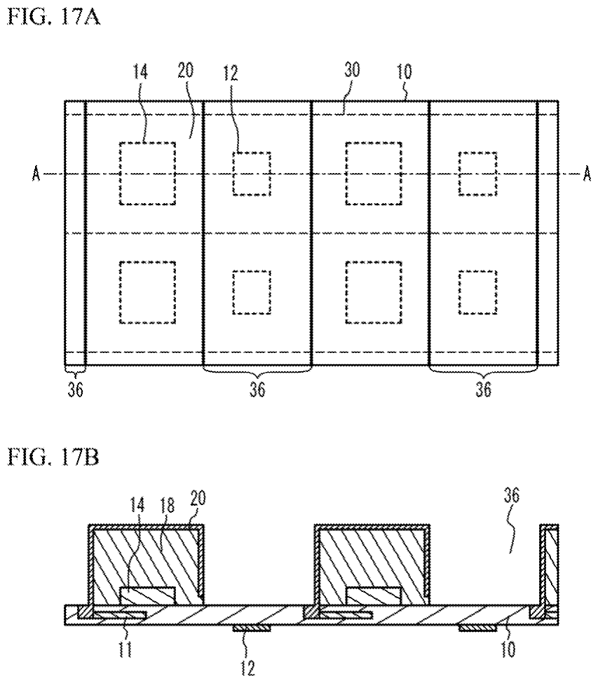

As illustrated in FIG. 17A and FIG. 17B, with use of the same method as the method described in FIG. 12A and FIG. 12B, the shield layer 20 and the sealing resin 18 between the grooves 32 and 34 in the region overlapping with the antenna 12 are removed. This process exposes the upper surface of the substrate 10 in the recessed portion 36 between the grooves 32 and 34. The sealing resin 18 may be slightly left on the upper surface of the substrate 10.

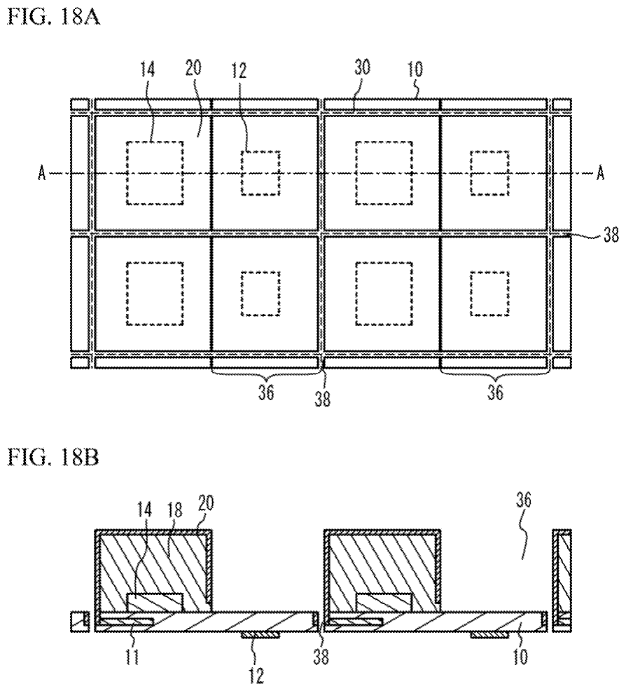

As illustrated in FIG. 18A and FIG. 18B, with use of the same method as the method described in FIG. 13A and FIG. 13B, the cutting grooves 38 are formed in the shield layer 20 and the substrate 10 in the section lines 30. This process separates wireless modules into individual wireless modules.

As illustrated in FIG. 19, the region where the antenna 12 is located of the substrate 10 is immersed into a melted foamed resin 40 in a tank 42. Thereafter, when the substrate 10 is pulled out and solidified, the foamed resin 16 is formed on the upper surface and the lower surface in the region where the antenna 12 is located of the substrate 10. Through these processes, the wireless module of the seventh variation of the first embodiment is manufactured.

In the fourth embodiment, as illustrated in FIG. 14A through FIG. 18B, the sealing resin 18 is formed on the upper surface (a second surface), on which the electronic circuit 14 is mounted, of the substrate 10 that has the lower surface (a first surface) on which the antenna 12 is located. The sealing resin 18 is not located in the region overlapping with the antenna 12 in plan view, and seals the electronic circuit 14. As illustrated in FIG. 19, the foamed resin 16 is formed in the region overlapping with the antenna 12 of the upper surface of the substrate 10, and is formed on the lower surface of the substrate 10 so as to seal the antenna 12.

Accordingly, the foamed resin 16 is formed on the upper and lower surfaces of the substrate 10 so as to overlap with the antenna 12 in a simple way.

In the fourth embodiment, since the antenna 12 is located on the lower surface of the substrate 10, the groove 34 can be configured to be deeper than that of the third embodiment in FIG. 15A and FIG. 15B. Accordingly, the shield layer 20 is formed closer to the substrate 10 than that of the third embodiment. Thus, EMI is more reduced than that of the third embodiment.

The electronic circuit 14 and the sealing resin 18 may be located on a surface on which the antenna 12 is also located of the substrate 10.

### Fifth Embodiment

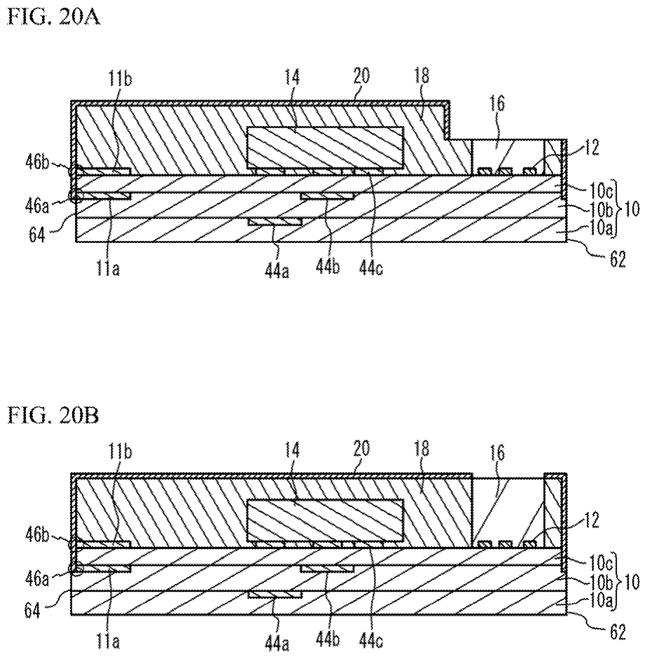

FIG. 20A and FIG. 20B are cross-sectional views of wireless modules of a fifth embodiment and a first variation thereof, respectively. As illustrated in FIG. 20A, in the fifth embodiment, the substrate 10 includes insulating layers 10a through 10c that are stacked. A wiring line 44a is located between the insulating layers 10a and 10b, and a wiring line 44b is located between the insulating layers 10b and 10c. A wiring line 44c is located on the upper surface of the substrate 10. The electronic circuit 14 is mounted to the wiring line 44c through a bump (not illustrated). Each of ground wiring lines 11a and 11b is a part of the wiring line 44b. The ground wiring lines 11a and 11b are electrically connected to the shield layer 20 in connection points 46a and 46b of the edge portion of the substrate 10, respectively. Other structures are the same as those of the fourth embodiment, and the description thereof is thus omitted.

As illustrated in FIG. 20B, in the first variation of the fifth embodiment, the thickness of the foamed resin 16 is approximately equal to the thickness of the sealing resin 18. Other structures are the same as those of the fifth embodiment, and the description thereof is thus omitted.

In the fifth embodiment and the first variation thereof, the planar shape of the substrate 10 is a rectangle (see FIG. 13A). The substrate 10 includes a first portion and a second portion. The antenna 12 is located in the first portion, which is closer to a side 62 (a first side) of the rectangle of the substrate 10 than the second portion, and has a conductive pattern. The electronic circuit 14 is located in the second portion, which is closer to a side 64 (a second side) facing the side 62 of the substrate 10 than the first portion. The foamed resin 16 seals the antenna 12. The sealing resin 18 seals at least a part of the electronic circuit 14.

In the above-described structure, since the foamed resin 16 includes void spaces, the foamed resin 16 has less environmental resistance. For example, water easily passes through the foamed resin 16. Since the shield layer 20 is not provided on the foamed resin 16, water penetrates from the upper surface of the foamed resin 16. When the water reaches the connection points 46a and 46b, the connection points 46a and 46b are oxidized or deteriorate by moisture adsorption. Thus, the contact resistance between the shield layer 20 and the ground wiring lines 11a and 11b increases. Thus, the shield layer 20 becomes insufficiently grounded.

Thus, the shield layer 20 (a shield) is electrically connected to the ground wiring lines 11a and 11b (or ground electrodes) in a location located away from the region where the foamed resin 16 is located. Accordingly, water penetrating from the foamed resin 16 is inhibited from reaching the connection points 46a and 46b between the shield layer 20 and the ground wiring lines 11a and 11b. Thus, the resistance of the connection points 46a and 46b is inhibited from increasing.

The shield layer 20 and the ground wiring lines 11a and 11b (ground electrodes) are connected on the side surface of the side 62 of the substrate 10 or on the upper surface near the side 62 of the substrate 10. Thus, the connection points 46a and 46b can be kept away from the foamed resin 16, and thus, the connection points 46a and 46b are further inhibited from deteriorating. In particular, the connection points 46a and 46b are preferably located in a first shorter side, which faces a second shorter side at which the antenna 12 is located, of the substrate 10.

In the fifth embodiment and the first variation thereof, the ground wiring line 11a is located inside the substrate 10 and on the upper surface of the substrate 10, but the ground wiring line 11a may be located inside the substrate 10 or on the upper surface of the substrate 10.

In the first through fourth embodiments and the variations thereof, the ground wiring line 11a and/or 11b may be provided.

Although the embodiments of the present invention have been described in detail, it is to be understood that the various change, substitutions, and alterations could be made hereto without departing from the spirit and scope of the invention.

What is claimed is:

1. A wireless module comprising:
a substrate having a first surface and a second surface, the second surface being an opposite surface of the substrate from the first surface;
an antenna located on the first surface;
an electronic circuit that is located on the first surface and/or the second surface, and outputs a high-frequency signal to the antenna and/or receives a high-frequency signal from the antenna; and
a foamed resin located on the first surface so as to seal the antenna.

2. The wireless module according to claim 1, wherein the foamed resin does not cover the electronic circuit.

3. The wireless module according to claim 2, wherein
the electronic component is located so as not to overlap with the antenna in a thickness direction of the substrate; and
the wireless module further comprises a sealing resin that is located on a surface on which the electronic circuit is located of the first surface and the second surface so as to seal the electronic circuit, a density of the sealing resin being greater than a density of the foamed resin.

4. The wireless module according to claim 3, wherein the sealing resin does not overlap with the antenna in the thickness direction of the substrate.

5. The wireless module according to claim 3, wherein the sealing resin is provided so as to cover the foamed resin.

6. The wireless module according to claim 5, wherein a thickness of the sealing resin on the foamed resin is less than a thickness of the sealing resin on the electronic circuit.

7. The wireless module according to claim 3, further comprising
a shield layer that covers the sealing resin, and does not overlap with the antenna in the thickness direction of the substrate.

8. The wireless module according to claim 3, wherein
a density of the sealing resin is equal to or greater than five times a density of the foamed resin.

9. The wireless module according to claim 1, wherein
the foamed resin seals the electronic circuit.

10. The wireless module according to claim 1, wherein
the foamed resin is located on the first surface and the second surface of the substrate so as to overlap with the antenna in a thickness direction of the substrate.

11. An electronic device comprising:
a mounting board having an upper surface on which an electronic component is mounted;
a wireless module that is mounted on the upper surface of the mounting board, and includes a substrate, an antenna located on an upper surface of the substrate, an electronic circuit that is located on the upper surface of the substrate and outputs a high-frequency signal to the antenna and/or receives a high-frequency signal from the antenna, and a foamed resin that seals the antenna and does not cover the electronic circuit; and
a sealing resin integrally sealing the electronic component and the electronic circuit.

12. A wireless module comprising:
a substrate of which a planar shape is a rectangle, the substrate having a first portion and a second portion;
an antenna having a conductive pattern located in the first portion, the first portion being located closer to a first side of the rectangle of the substrate than the second portion;
an electronic circuit located in the second portion, the second portion being located closer to a second side facing the first side of the substrate than the first portion;
a foamed resin sealing the antenna;
a sealing resin that seals at least a part of the electronic circuit; and
a shield that is electrically connected to a ground wiring line or a ground electrode in a location located away from a region where the foamed resin is located, and seals the sealing resin.

13. The wireless module according to claim 12, wherein the ground wiring line or the ground electrode are located inside the substrate and/or on a surface of the substrate.

14. The wireless module according to claim 12, wherein the shield and the ground wiring line or the ground electrode are connected on a side surface of the second side of the substrate.
